(19) United States
(12) Patent Application Publication
(10) Pub. No.: US 2008/0121948 A1
(43) Pub. Date: May 29, 2008

(54) FINFET drive strength de-quantization using multiple orientation fins

(75) Inventors: Jae-Joon Kim, Yorktown Heights, NY (US); Rahul M. Rao, Elmsford, NY (US)

Correspondence Address: RYAN, MASON & LEWIS, LLP, 1300 POST ROAD, SUITE 205, FAIRFIELD, CT, 06824, US

(73) Assignee: International Business Machines Corporation, Armonk, NY (US)

(21) Appl. No.: 11/505,224

(22) Filed: Aug. 16, 2006

(51) Int. Cl. H01L 27/088; H01L 27/06; G06F 17/50

(52) U.S. Cl. 257/255; 716/10; 257/E27.026; 257/E27.06

(57) ABSTRACT

A fin-type field effect transistor (FINFET) includes a plurality of fins forming drain-source regions and a gate region disposed about the fins. At least a first one of the fins has a first crystal orientation, and at least a second one of the fins has a second crystal orientation that is different from the first crystal orientation. The second crystal orientation is selected to be different from the first crystal orientation to reduce a drive strength quantization error of the transistor. Circuits using such FETS and methods for designing such circuits are also presented.

### FIELD OF THE INVENTION

The present invention generally relates to electronic devices and circuits and, more particularly, to fin-type field effect transistors (FINFETS) and FINFET circuits.

### BACKGROUND OF THE INVENTION

The need for innovation to scale conventional metal-oxide semiconductor field effect transistor (MOSFET) devices to deep sub-micron regimes has become greater than ever before. With conventional scaling being faced with severe challenges in short channel effects, increased leakage (or decreased ratio of ON to OFF current (Iₒₙ/I_{off} ratio)), gate leakage, and the like, a variety of device structures are being explored as alternative solutions. See E. Nowak, et. al, “Turning Silicon On Its Edges,” IEEE Circuits and Devices Magazine, 20(1):20-31, January-February 2004, and E. Nowak, et. al, “Scaling Beyond the 65-nm Node with FINFET-DGMOS,” Proceedings of IEEE Custom Integrated Circuits Conference, pp. 339-342, 2003.

Alternative surface orientations and locally induced strains are also being considered to further enhance the performance and power characteristics of nanometer designs. See L. Chang, M. Ieong, & M. Yang, “CMOS Circuit Performance Enhancement by Surface Orientation Optimization,” IEEE Transactions on Electron Devices, vol. 51, no. 10, pp. 1621-1627, October 2004, and M. Yang, et. al, “Performance dependence of CMOS on Silicon Substrate Orientation for Ultrathin Oxynitride and HfO2 Gate Dielectrics,” IEEE Electron Device Letters, vol. 24, pp. 339-341, May 2003. Among these various choices, fin-type field effect transistor (FINFET) technology has emerged as a strong candidate due to its manufacturing ease (relative to other design choices) and superior short channel effects. See T. Ludwig, et. al, “FinFET Technology for Future Microprocessors,” Proceedings of IEEE SOI Conference, pp. 33-34, 2003.

Although a FINFET has a very similar manufacturing process and characteristics as compared to planar silicon devices, circuit designs using FINFETS require certain design accommodations. Designers in planar technologies have been relatively unconstrained in selecting device widths, such that appropriate ratios of drive strength in N-MOSFET and P-MOSFET devices will achieve desired trade-offs in performance, power consumption, and noise immunity. However, in a FINFET, the device width quantum is determined by the height H of the fin, with each fin providing 2H of device width. With such quantization in device width, it becomes more difficult to achieve desired beta ratios using FINFETS, which places a constraint on the power-performance tradeoffs associated with the designs.

The device-width quantization problem is considerably more severe for circuits sensitive to the beta ratio of the devices used. These include static random access memory (SRAM) cells, latches, analog and dynamic circuits. To achieve comparable flexibility using FINFETS, more fins having potentially longer channel lengths may be needed to achieve a given beta ratio. The beta ratio may be defined, in general, as the ratio of the conductance of a first transistor to that of a second transistor. By way of a specific example, not intended to be limiting, designers of CMOS SRAM may define the “beta ratio” of a cell as the ratio of the conductance of the pull-down device over the conductance of the pass-gate device. The larger the beta ratio, the more stable the cell becomes (its static noise margin (SNM) increases, as well).

The conductance of a transistor is approximately proportional to the effective carrier mobility μ_{f} and to the ratio of the device width to the channel length (W/L). The beta of the SRAM cell can be approximated by the ratio of μ_{f} (W/L) of the pull-down transistor and μ_{f} (W/L) of the pass-gate. If the transistors have the same channel length, then the beta ratio becomes the ratio of the channel width of N1 over the channel width of NL.

FIG. 1 shows the cross-section of a typical multi-fin FINFET device 100 (not to scale). The silicon body can be turned to a vertical orientation creating a ‘fin’ 102, with the source and drain being placed horizontally along the fin. The poly-silicon gate 104 wraps over the fin, covering it on three sides and defines the width of the device. The current flow occurs along an orthogonal crystal plane in a direction parallel to the wafer plane. The height of the fin (H) is typically determined by the thickness of the silicon film on a SOI wafer, and hence is a constant for all fins 102. The thickness of the fin (T_{fi}) determines the short channel behavior of the device and is usually small in comparison with the height H of the fin. The pitch P of the fins is determined by lithographic constraints and dictates the wafer area to implement the desired device width W. A small value of P and a large value of H enable a better packing of the devices per square area resulting in a denser design (or more efficient use of silicon wafer area).

As can be seen, the width of a single fin is determined by the height of the fin and can be represented as 2H+T_{fi}. With the thickness of the fin being small in comparison with the height of the fin, this can be approximated as 2H. In addition, the width of the device can be increased only in integral multiples of the single-fin width, that is, the width of any device is given by 2nH, with n being the number of fins. This is in contrast to designs in a planar technology, where the width can be increased in increments of the design grid providing an almost continuous selection of device width. Hence, achieving a required beta ratio is more difficult in FINFET technology and can constrain the characteristics of beta ratio-sensitive circuits.

It would be desirable to overcome the limitations in previous approaches.

### SUMMARY OF THE INVENTION

Principles of the present invention provide techniques for FINFET drive strength de-quantization using multiple orientation fins. In one aspect, an exemplary fin-type field effect transistor (FINFET) includes a plurality of fins forming drain-source regions and a gate region disposed about the fins. At least a first one of the fins has a first crystal orientation, and at least a second one of the fins has a second crystal orientation that is different from the first crystal orientation. The second crystal orientation is selected to be different from the first crystal orientation to reduce a drive strength quantization error of the transistor.

In another aspect, a field effect transistor (FET) circuit includes a plurality of FINFETS that are operatively coupled. At least a first one of the FINFETS and at least a second one of the FINFETS have a desired β ratio. At least one of the first FINFET and the second FINFET comprises a plurality of fins forming drain-source regions, and a gate region disposed about the fins. At least a first one of the fins has a first crystal orientation. At least a second one of the fins has a second crystal orientation that is different from the first crystal orientation. The second crystal orientation is selected to be different from the first crystal orientation to achieve the desired β ratio with lower die area and/or reduced capacitance as compared to an otherwise equivalent FET circuit wherein all FINFET fins have an identical crystal orientation.

In still another aspect, an exemplary method of designing a field effect transistor (FET) circuit comprising a plurality of FINFETS that are operatively coupled includes the steps of identifying at least a first one of the FINFETS and at least a second one of the FINFETS having a desired β ratio, specifying at least one of the first FINFET and the second FINFET to have a plurality of fins forming drain-source regions, and a gate region disposed about the fins, and selecting the second crystal orientation to be different from the first crystal orientation to achieve the desired β ratio. At least a first one of the fins has a first crystal orientation, and at least a second one of the fins has a second crystal orientation that is different from the first crystal orientation. The desired β ratio can be achieved with lower die area and/or reduced capacitance as compared to an otherwise equivalent FET circuit wherein all FINFET fins have an identical crystal orientation.

One or more embodiments of the present invention may be realized in the form of an integrated circuit.

One or more embodiments of the invention (for example, the aforementioned method of designing a circuit) can be implemented in the form of a computer product including a computer usable medium with computer usable program code for performing the method steps indicated. Furthermore, one or more embodiments of the invention (for example, a workstation implementing the design method) can be implemented in the form of an apparatus including a memory and at least one processor that is coupled to the memory and operative to perform exemplary method steps.

These and other objects, features and advantages of the present invention will become apparent from the following detailed description of illustrative embodiments thereof, which is to be read in connection with the accompanying drawings.

### BRIEF DESCRIPTION OF THE DRAWINGS

FIG. 1 shows a prior-art multi-fin FINFET device;

FIG. 2 shows exemplary electron mobility along different surface orientations;

FIG. 3 shows exemplary hole mobility along different surface orientations;

FIG. 4 shows a multiple (two) orientation FINFET used to obtain desired drive strength of a device (assuming a <110> base wafer orientation), according to an exemplary embodiment of the invention;

FIG. 5 shows a multiple (three) orientation FINFET used to obtain desired drive strength of a device (assuming a <110> base wafer orientation) according to another exemplary embodiment of the invention;

FIG. 6 shows a top view of the embodiment of FIG. 5;

FIG. 7 shows an exemplary graph of quantization error in drive strength;

FIG. 8 shows an exemplary graph of percentile quantization error in derive strength;

FIG. 9 shows an exemplary inventive transistor circuit;

FIG. 10 is a flow chart showing exemplary inventive method steps; and

FIG. 11 depicts a computer system that may be useful in implementing one or more aspects and/or elements of the present invention.

### DETAILED DESCRIPTION OF PREFERRED EMBODIMENTS

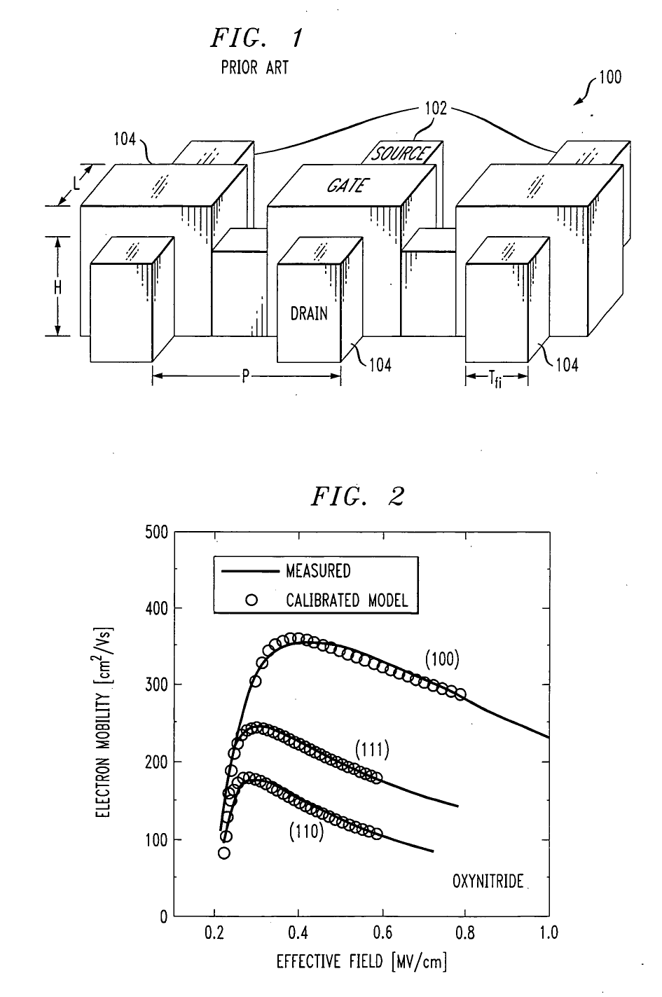

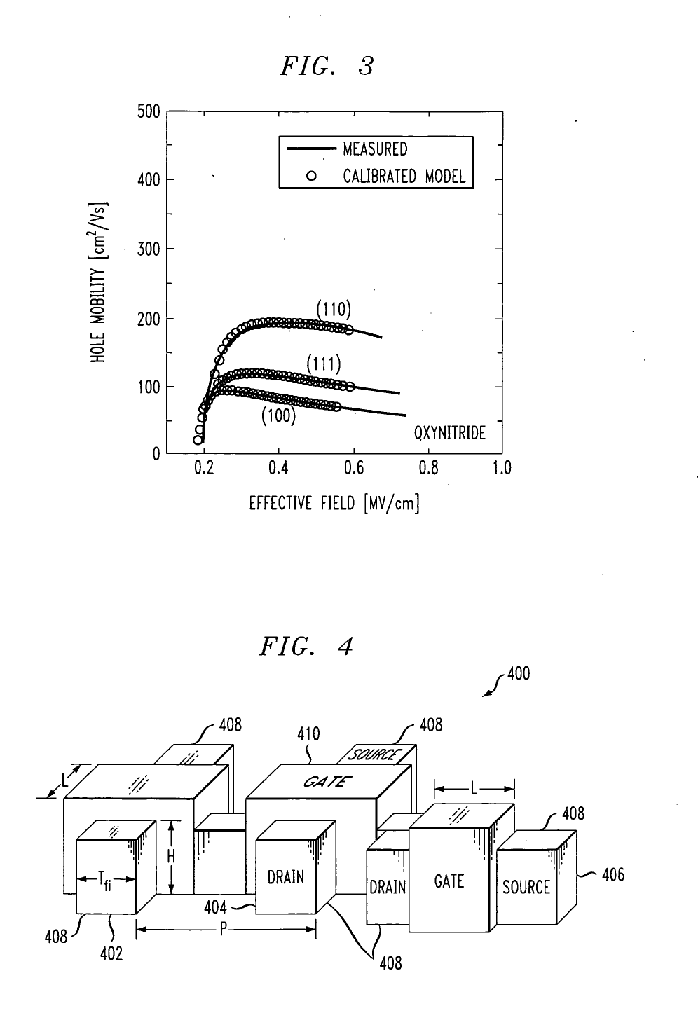

The drive strength (or beta) of a device depends on its physical dimensions (Width, Length) and carrier mobility in addition to certain other process parameters and constants. The carrier mobility is dependent on the crystal orientation in the direction of current flow. Although <100> is the typical wafer orientation, the difference in the carrier effective mass along different crystal orientations results in a change in the carrier mobility when non-<100> surface orientations are used. This is illustrated in FIGS. 2 and 3, where the relative mobility of electrons and holes along different carrier orientations (as labeled) is shown as a function of the effective field (See L. Chang, M. Ieong, & M. Yang, supra). It is clearly seen that the mobility along one orientation can be over a factor of 2 greater than the mobility along the other orientation (for both holes and electrons). However, the effective change in drive current is expected to be much lower, at around 10-15%, due to velocity saturation effects. Since the mobility directly impacts the drive strength, the beta of the device can be altered by changing the orientation of the device.

Traditionally, aligning of devices along multiple orientations is avoided due to the process complexity involved in manufacturing different crystal orientations in close proximity on the same planar silicon wafer. However, in FINFET technology, the device is in a vertical orientation, and hence in a plane normal to the plane of the wafer. As a result, devices along non-<100> orientations can be achieved by simply rotating the devices in the vertical plane. In other words, rotating the direction of the poly-silicon in the layout would result in a non-<100> FINFET device, which would exhibit a different mobility and hence different drive strength for the same total width of the device. This aspect of the invention allows one to obtain devices of required drive strength.

With the fin height being H, the device widths possible using a FINFET structure are given by 2nH, where n represents the number of fins. Traditionally, these devices are oriented only along the <100> direction (which has a mobility u₁) and hence the drive strength (DS) of devices is given by 2nHu₁k, where k is derived from process and system constants in a manner known to the skilled artisan. However, if we desire a width of (2n−1) H, it would not be possible using prior-art techniques.

Thus, the difference between the intended drive strength and achievable drive strength (termed as quantization error) is

QE=(2n−(2n−1))u₁kH=u₁kH (1)

The percentage quantization error is given by

QEP=100u₁kH/[(2n−1)u₁kH]=100/(2n−1) (2)

This quantization error can be minimized by orienting some fingers (fins) along non-<100> orientations. For instance, if n₁ fins are oriented along the <100> direction and n₂ fins are oriented along the <110> direction, then the effective drive strength of the device is given by

DS=k(2n₁u₁H+2n₂u₂H) (3)

where:

k is derived from process and system constants (as k does not depend on orientation, and is decided by process technology and system constraints which are independent of orientation, the single orientation case and multiple-orientation case will have same the k),

n₁ is the number of fins having the first crystal orientation,

n₂ is the number of fins having the second crystal orientation,

u₁ is the mobility associated with the first crystal orientation,

u₂ is the mobility associated with the second crystal orientation, and

H is the height of the fins.

Thus, the absolute and percent quantization error are given by

QE=2Hk(n₁u₁+n₂u₂)−(2n−1)u₁kH (4)

QEP=100[2(n₁u₁+n₂u₂)−(2n−1)u₁]/[(2n−1)u₁] (5)

By proper selection of n₁ and n₂, the quantization error can be minimized and a device strength closer to the intended device strength can be obtained. An exemplary implementation of this nature is illustrated in FIG. 4, showing a device 400 in which two fins 402, 404 are oriented along the <100> direction and one fin 406 is placed along the <110> orientation (on a <110> wafer). In case a <100> base wafer is used, the devices would need to be rotated by 45° to align them along <110> orientation.

It will be appreciated that the orientations shown are exemplary and other orientations could be employed. In general, device 400 is representative of a FINFET, comprising a plurality of fins 402, 404, 406 forming drain-source regions 408, and a gate region 410 disposed about the fins. At least a first one of the fins has a first crystal orientation (in this case, two fins, 402, and 404). At least a second one of the fins (in this case, 408) has a second crystal orientation that is different from the first crystal orientation. The second crystal orientation is selected to be different from the first crystal orientation to reduce a drive strength quantization error of the transistor 400. The drive strength of device 400 is substantially given by equation (3) above. The numbers of fins n₁ and n₂ are preselected to obtain a desired value of DS not available in an otherwise comparable transistor having fins of only a single crystal orientation (that is, a transistor with all materials, numbers of fins and dimensions substantially similar except all fins having the same orientation).

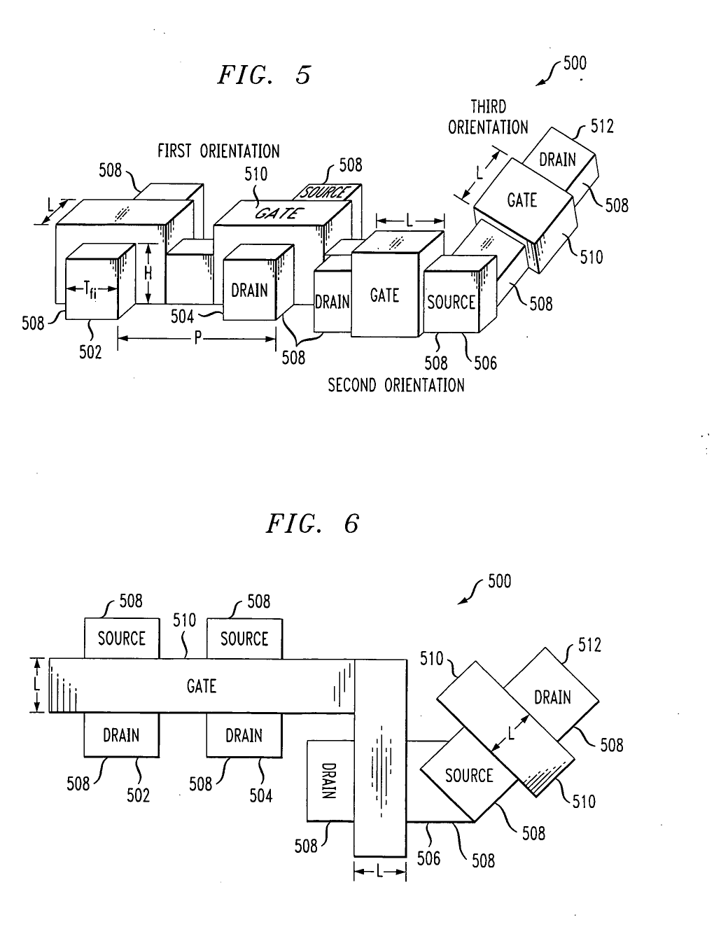

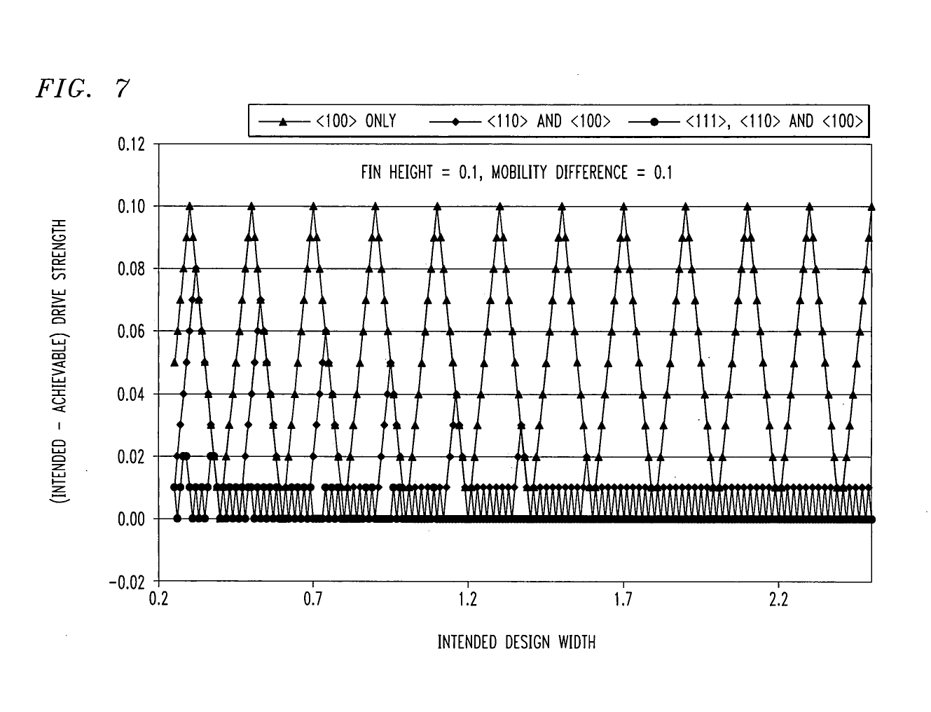

Attention should now be given to FIGS. 5 and 6 (FIG. 6 is a top view of the device of FIG. 5). FIGS. 5 and 6 show an exemplary device similar to FIG. 4 except that three crystal orientations are employed. The first crystal orientation is <100>, the second crystal orientation is <110>, and the third crystal orientation is <111>. Similar elements have received the same reference character as in FIG. 4, incremented by one hundred. It will be appreciated that, if three different orientations are available, the device strength can be represented as:

DS=k(2n₁u₁H+2n₂u₂H+2n₃u₃H) (6)

where:

k is derived from process and system constants,

n₁ is the number of fins having the first crystal orientation,

n₂ is the number of fins having the second crystal orientation,

n₃ is the number of fins having the third crystal orientation,

u₁ is the mobility associated with the first crystal orientation,

u₂ is the mobility associated with the second crystal orientation,

u₃ is the mobility associated with the third crystal orientation, and

H is the height of the fins.

In this case, the quantization error can be further reduced. The transistor of FIGS. 5 and 6 makes use of a third crystal orientation that is different from the first crystal orientation and the second crystal orientation. Fin 512 uses the third orientation. The number of fins n₁, n₂, and n₃ can be preselected to obtain a desired value of DS not available in an otherwise comparable transistor having fins of only a single crystal orientation or fins of only two crystal orientations. Again, otherwise comparable means that materials, dimensions, and numbers of fins are substantially the same and only the orientations are different.

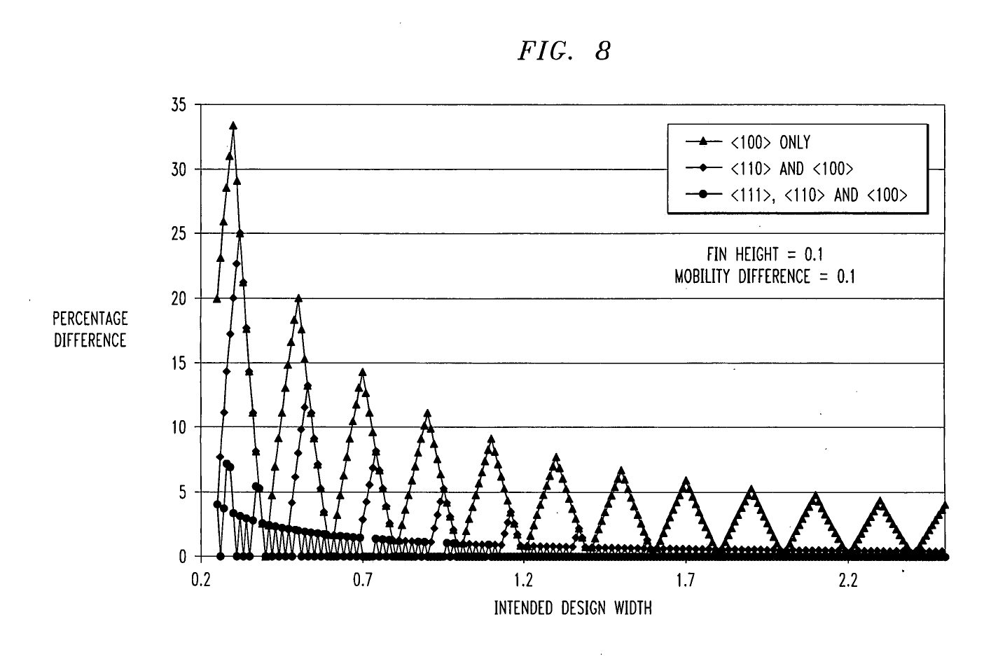

For purely illustrative purposes, dimensions equivalent to a 90 nm device technology with a minimum design width of Wₘᵢₙ=0.25 um (in a planar technology) were considered. It was assumed, again for illustrative purposes only, that the maximum differential in drive strength along <100> and <110> orientations was 10%, with an n-type MOS (NMOS) along the <110> orientation being 10% slower than an NMOS along the <100> orientation (that is, u₁/u₂=0.9). A fin height of H=100 nm was also assumed. With these parameters, the quantization error and percentage quantization error in the drive strengths were determined for devices with widths ranging from 0.25 um to 2.5 um. FIG. 7 shows the quantization error (QE) against the intended drive strength. The three curves represent the possibility of the fins being aligned along one (<100> only), two (<110> and <100>) and three (<111>, <110> and <100>) orientations respectively. In case of multiple orientations, the number of fins that are aligned along each orientation is determined to minimize the quantization error. The corresponding percentile quantization error is shown in FIG. 8. It can be clearly seen that using the multiple orientation approach, the quantization error (and the percentile quantization error) in drive strength can be considerably reduced, thereby enabling the design of beta-ratio sensitive circuits. Similar experiments were carried out with different fin heights (ranging from H=70 nm to H=130 nm) and mobility differences (ranging from u=0.5 to u=1.5) with reduction in quantization error being seen in each case. It is to be emphasized that this paragraph and FIGS. 7 and 8 are for purposes of illustrating exemplary benefits obtained in certain specific cases, and are not to be taken as limiting.

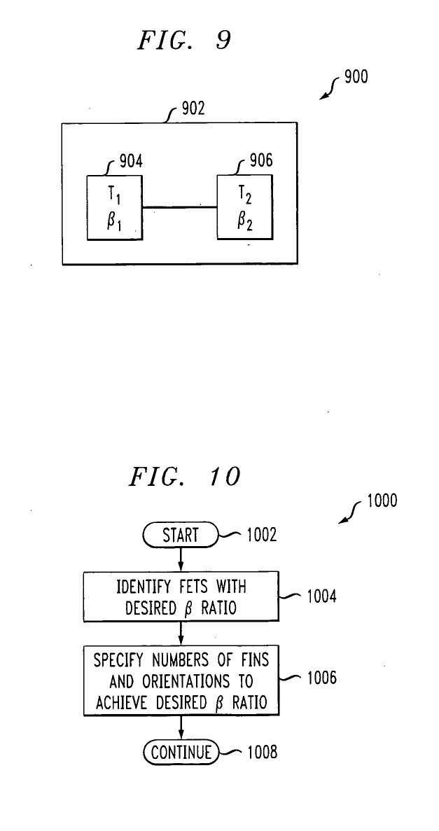

FIG. 9 shows an exemplary FET circuit comprising a plurality of FINFETS; two such FINFETS 904 and 906 are shown in block form for illustrative convenience (as many as are required can be present in the circuit). The circuit can be implemented, for example, as an integrated circuit 902. The FINFETS 904, 906 are operatively coupled (as suggested by the connecting line), that is, connected in a useful circuit either directly or through other elements or components. Circuit 900 can be, for example, an SRAM circuit, a latch, an analog circuit, or a dynamic circuit. At least a first one of the FINFETS and at least a second one of the FINFETS have a desired β ratio. For example, T₁ may have a β value of β₁ and T₂ may have a β value of β₂, and the ratio of β₁ to β₂ may take on a desired value. At least one of the first FINFET 904 and the second FINFET 906 employs multi-orientation fins as described above, to achieve lower die area and/or reduced capacitance as compared to an otherwise equivalent FET circuit wherein all FINFET fins have an identical crystal orientation. The drive strengths are given by the equations above and the number of fins and their orientation may be selected as described above. Two or three orientations may be used, in one or more of the transistors.

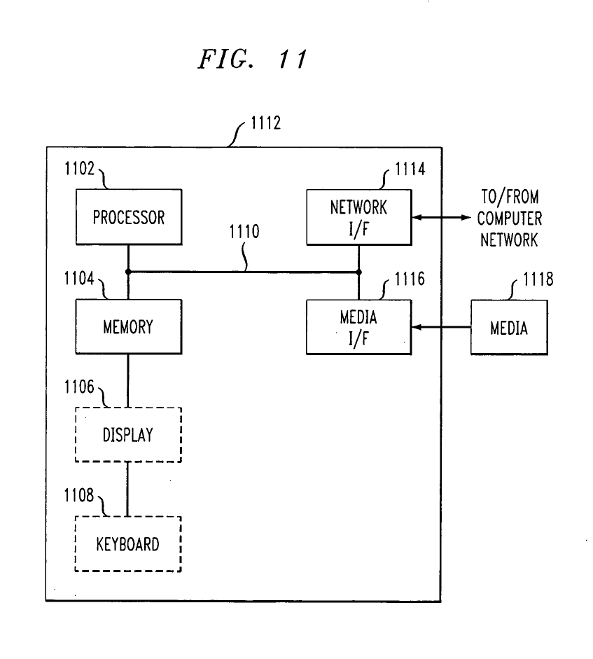

FIG. 10 shows a flow chart 1000 of exemplary steps in a method of designing a field effect transistor (FET) circuit of the kind just described. In step 1004, at least a first one of the FINFETS and at least a second one of the FINFETS having a desired β ratio are identified. In step 1006, one specifies at least one of the first FINFET and the second FINFET to have multiple orientation fins as described above, to achieve the desired β ratio with lower die area and/or reduced capacitance as compared to an otherwise equivalent FET circuit wherein all FINFET fins have an identical crystal orientation. The selecting of the orientations and specification of the numbers of fins can be thought of as separate steps or part of a single comprehensive step 1006 as shown in FIG. 10. Equations (3) or (6) as appropriate can be employed to select the second crystal orientation and at least the number of fins n₂ (as well as, of course, numbers of fins in other orientations, and the like). Processing continues at block 1008. The equations can be applied iteratively if desired to converge on an appropriate solution.

At least a portion of the techniques of one or more aspects or embodiments of the present invention described herein may be implemented in an integrated circuit. In forming integrated circuits, a plurality of identical die are typically fabricated in a repeated pattern on a surface of a semiconductor wafer. Each die can include one or more of the devices or circuits described herein, and may include other devices, structures or circuits. The individual die are cut or diced from the wafer, then packaged as an integrated circuit. A person of skill in the art will know how to dice wafers and package die to produce integrated circuits. Integrated circuits so manufactured are considered part of the present invention. Circuits including cells as described above can be part of the design for an integrated circuit chip. The chip design can be created, for example, in a graphical computer programming language, and stored in a computer storage medium (such as a disk, tape, physical hard drive, or virtual hard drive such as in a storage access network). If the designer does not fabricate chips or the photolithographic masks used to fabricate chips, the designer may transmit the resulting design by physical means (for example, by providing a copy of the storage medium storing the design) or electronically (for example, through the Internet) to such entities, directly or indirectly. The stored design can then be converted into an appropriate format such as, for example, Graphic Design System II (GDSII), for the fabrication of photolithographic masks, which typically include multiple copies of the chip design in question that are to be formed on a wafer. The photolithographic masks can be utilized to define areas of the wafer (and/or the layers thereon) to be etched or otherwise processed.

Resulting integrated circuit chips can be distributed by the fabricator in raw wafer form (that is, as a single wafer that has multiple unpackaged chips), as a bare die or in a packaged form. In the latter case, the chip can be mounted in a single chip package (such as a plastic carrier, with leads that are affixed to a mother board or other higher level carrier) or in a multi-chip package (such as a ceramic carrier that has either or both surface interconnections or buried interconnections). In any case, the chip may then be integrated with other chips, discrete circuit elements and/or other signal processing devices as part of either (a) an intermediate product, such as a mother board, or (b) an end product. The end product can be any product that includes integrated circuit chips, ranging from toys and other low-end applications to advanced computer products having a display, a keyboard or other input device, and a central processor.

A variety of techniques, utilizing dedicated hardware, general purpose processors, firmware, software, or a combination of the foregoing may be employed to implement the present invention (for example, the design method can be computer-implemented using software on a workstation). One or more embodiments of the invention can be implemented in the form of a computer product including a computer usable medium with computer usable program code for performing the method steps indicated. Furthermore, one or more embodiments of the invention can be implemented in the form of an apparatus including a memory and at least one processor that is coupled to the memory and operative to perform exemplary method steps.

At present, it is believed that the preferred implementation for automating the design method (which can result a stored design as described above) will make substantial use of software running on a general purpose computer or workstation. With reference to FIG. 11, such an implementation might employ, for example, a processor 1102, a memory 1104, and an input/output interface formed, for example, by a display 1106 and a keyboard 1108. The term “processor” as used herein is intended to include any processing device, such as, for example, one that includes a CPU (central processing unit) and/or other forms of processing circuitry. Further, the term “processor” may refer to more than one individual processor. The term “memory” is intended to include memory associated with a processor or CPU, such as, for example, RAM (random access memory), ROM (read only memory), a fixed memory device (for example, hard drive), a removable memory device (for example, diskette), a flash memory and the like. In addition, the phrase “input/output interface” as used herein, is intended to include, for example, one or more mechanisms for inputting data to the processing unit (for example, mouse), and one or more mechanisms for providing results associated with the processing unit (for example, printer). The processor 1102, memory 1104, and input/output interface such as display 1106 and keyboard 1108 can be interconnected, for example, via bus 1110 as part of a data processing unit 1112. Suitable interconnections, for example via bus 1110, can also be provided to a network interface 1114, such as a network card, which can be provided to interface with a computer network, and to a media interface 1116, such as a diskette or CD-ROM drive, which can be provided to interface with media 1118.

Accordingly, computer software including instructions or code for performing the methodologies of the invention, as described herein, may be stored in one or more of the associated memory devices (for example, ROM, fixed or removable memory) and, when ready to be utilized, loaded in part or in whole (for example, into RAM) and executed by a CPU. Such software could include, but is not limited to, firmware, resident software, microcode, and the like.

Furthermore, the invention can take the form of a computer program product accessible from a computer-usable or computer-readable medium (for example, media 1118) providing program code for use by or in connection with a computer or any instruction execution system. For the purposes of this description, a computer usable or computer readable medium can be any apparatus for use by or in connection with the instruction execution system, apparatus, or device.

The medium can be an electronic, magnetic, optical, electromagnetic, infrared, or semiconductor system (or apparatus or device) or a propagation medium. Examples of a computer-readable medium include a semiconductor or solid-state memory (for example memory 1104), magnetic tape, a removable computer diskette (for example media 1118), a random access memory (RAM), a read-only memory (ROM), a rigid magnetic disk and an optical disk. Current examples of optical disks include compact disk-read only memory (CD-ROM), compact disk-read/write (CD-R/W) and DVD.

A data processing system suitable for storing and/or executing program code will include at least one processor 1102 coupled directly or indirectly to memory elements 1104 through a system bus 1110. The memory elements can include local memory employed during actual execution of the program code, bulk storage, and cache memories which provide temporary storage of at least some program code in order to reduce the number of times code must be retrieved from bulk storage during execution.

Input/output or I/O devices (including but not limited to keyboards 1108, displays 1106, pointing devices, and the like) can be coupled to the system either directly (such as via bus 1110) or through intervening I/O controllers (omitted for clarity).

Network adapters such as network interface 1114 may also be coupled to the system to enable the data processing system to become coupled to other data processing systems or remote printers or storage devices through intervening private or public networks. Modems, cable modem and Ethernet cards are just a few of the currently available types of network adapters.

In any case, it should be understood that the components illustrated herein may be implemented in various forms of hardware, software, or combinations thereof, for example, application specific integrated circuit(s) (ASICS), functional circuitry, one or more appropriately programmed general purpose digital computers with associated memory, and the like. Given the teachings of the invention provided herein, one of ordinary skill in the related art will be able to contemplate other implementations of the components of the invention.

It will be appreciated and should be understood that the exemplary embodiments of the invention described above can be implemented in a number of different fashions. Given the teachings of the invention provided herein, one of ordinary skill in the related art will be able to contemplate other implementations of the invention.

Although illustrative embodiments of the present invention have been described herein with reference to the accompanying drawings, it is to be understood that the invention is not limited to those precise embodiments, and that various other changes and modifications may be made by one skilled in the art without departing from the scope of spirit of the invention.

What is claimed is:

1. A fin-type field effect transistor (FINFET), comprising:
a plurality of fins forming drain-source regions; and
a gate region disposed about said fins;
wherein:
at least a first one of said fins has a first crystal orientation, and at least a second one of said fins has a second crystal orientation that is different from said first crystal orientation; and
said second crystal orientation is selected to be different from said first crystal orientation to reduce a drive strength quantization error of said transistor.

2. The transistor of claim 1, wherein said first crystal orientation is <100> and said second crystal orientation is <110>.

3. The transistor of claim 1, wherein a drive strength, DS, of said transistor is substantially given by:
DS=k(2n₁u₁H+2n₂u₂H)
where:
k is derived from process and system constants,
n₁ is a number of said fins having said first crystal orientation,
n₂ is a number of said fins having said second crystal orientation,
u₁ is a mobility associated with said first crystal orientation,
u₂ is a mobility associated with said second crystal orientation, and
H is a height of said fins.

4. The transistor of claim 3, wherein n₁ and n₂ are preselected to obtain a desired value of DS not available in an otherwise comparable transistor having fins of only a single crystal orientation.

5. The transistor of claim 1, wherein at least a third one of said fins has a third crystal orientation that is different from said first crystal orientation and said second crystal orientation.

6. The transistor of claim 5, wherein said first crystal orientation is <100>, said second crystal orientation is <110>, and said third crystal orientation is <111>.

7. The transistor of claim 5, wherein a drive strength, DS, of said transistor is substantially given by:
DS=k(2n₁u₁H+2n₂u₂H+2n₃u₃H)
where:
k is derived from process and system constants,
n₁ is a number of said fins having said first crystal orientation,
n₂ is a number of said fins having said second crystal orientation,
n₃ is a number of said fins having said third crystal orientation,
u₁ is a mobility associated with said first crystal orientation,
u₂ is a mobility associated with said second crystal orientation,
u₃ is a mobility associated with said third crystal orientation, and
H is a height of said fins.

8. The transistor of claim 7, wherein n₁, n₂, and n₃ are preselected to obtain a desired value of DS not available in an otherwise comparable transistor having one of:
fins of only a single crystal orientation; and
fins of only two crystal orientations.

9. A field effect transistor (FET) circuit comprising a plurality of fin-type FETS (FINFETS), said FINFETS being operatively coupled, wherein:
at least a first one of said FINFETS and at least a second one of said FINFETS have a desired β ratio; and
at least one of said first FINFET and said second FINFET comprises a plurality of fins forming drain-source regions, and a gate region disposed about said fins, at least a first one of said fins having a first crystal orientation, and at least a second one of said fins having a second crystal orientation that is different from said first crystal orientation, said second crystal orientation being selected to be different from said first crystal orientation to achieve said desired β ratio with at least one of:
lower die area; and
reduced capacitance
as compared to an otherwise equivalent FET circuit wherein all FINFET fins have an identical crystal orientation.

10. The circuit of claim 9, wherein a drive strength, DS, of said at least one of said FINFETS is substantially given by:
DS=k(2n₁u₁H+2n₂u₂H)
where:
k is derived from process and system constants,
n₁ is a number of said fins having said first crystal orientation,
n₂ is a number of said fins having said second crystal orientation,
u₁ is a mobility associated with said first crystal orientation,
u₂ is a mobility associated with said second crystal orientation, and
H is a height of said fins.

11. The circuit of claim 10, wherein n₁ and n₂ are preselected to obtain said desired β ratio.

12. The circuit of claim 9, wherein at least a third one of said fins has a third crystal orientation that is different from said first crystal orientation and said second crystal orientation.

13. The circuit of claim 12, wherein a drive strength, DS, of said transistor is substantially given by:
DS=k(2n₁u₁H+2n₂u₂H+2n₃u₃H)
where:
k is derived from process and system constants,
n₁ is a number of said fins having said first crystal orientation,
n₂ is a number of said fins having said second crystal orientation,
n₃ is a number of said fins having said third crystal orientation,
u₁ is a mobility associated with said first crystal orientation,
u₂ is a mobility associated with said second crystal orientation,
u₃ is a mobility associated with said third crystal orientation, and
H is a height of said fins.

14. The circuit of claim 13, wherein n₁, n₂, and n₃ are preselected to obtain said desired β ratio.

15. The circuit of claim 9, wherein said circuit comprises a static random access memory (SRAM) circuit.

16. The circuit of claim 9, wherein said circuit comprises a latch.

17. The circuit of claim 9, wherein said circuit comprises an analog circuit.

18. The circuit of claim 9, wherein said circuit comprises a dynamic circuit.

19. A method of designing a field effect transistor (FET) circuit comprising a plurality of fin-type FETS (FINFETS), said FINFETS being operatively coupled, said method comprising the steps of:
identifying at least a first one of said FINFETS and at least a second one of said FINFETS having a desired β ratio;
specifying at least one of said first FINFET and said second FINFET to have a plurality of fins forming drain-source regions, and a gate region disposed about said fins, at least a first one of said fins having a first crystal orientation, and at least a second one of said fins having a second crystal orientation that is different from said first crystal orientation; and
selecting said second crystal orientation to be different from said first crystal orientation to achieve said desired β ratio with at least one of:
lower die area; and
reduced capacitance
as compared to an otherwise equivalent FET circuit wherein all FINFET fins have an identical crystal orientation.

20. The method of claim 19, wherein a drive strength, DS, of said at least one FINFET is substantially given by the equation:
DS=k(2n₁u₁H+2n₂u₂H)
where:
k is derived from process and system constants,
n₁ is a number of said fins having said first crystal orientation,
n₂ is a number of said fins having said second crystal orientation,
u₁ is a mobility associated with said first crystal orientation,
u₂ is a mobility associated with said second crystal orientation, and
H is a height of said fins,
wherein said selecting step comprises applying said equation to select said second crystal orientation and at least said number of fins n₂.
